(19) United States
(12) Patent Application Publication
(10) Pub. No.: US 2024/0396508 A1
(43) Pub. Date: Nov. 28, 2024

(54) MODULATED POWER CONSUMPTION

(71) Applicant: SKYWORKS SOLUTIONS, INC., Irvine, CA (US)

(72) Inventors: Grant Darcy POULIN, Carp (CA); Wesley John BOYD, Coal Valley, IL (US); Hichem Ben Hedi Abdallah, Andover, MA (US); Chung Liang LEE, Irvine, CA (US)

(21) Appl. No.: 18/629,634

(22) Filed: Apr. 8, 2024

Related U.S. Application Data
(60) Provisional application No. 63/454,780, filed on Mar. 27, 2023.

(51) Int. Cl. H03F 3/24; H04B 1/40

(52) U.S. Cl. CPC H03F 3/245; H04B 1/40; H03F 2200/451

(57) ABSTRACT

A method includes receiving a first signal at a front-end module (FEM) comprising a power amplifier, the first signal indicating an increase in expected power or modulation, in response to receiving the first signal, increasing power at the power amplifier for one or more packets; and, after processing the one or more packets, reducing power at the power amplifier.

### RELATED APPLICATION

This application claims priority to U.S. Provisional Application No. 63/454,780, filed Mar. 27, 2023, and entitled MULTI-STATE POWER AMPLIFIER, the disclosure of which is hereby incorporated by reference in its entirety.

### BACKGROUND

### Field

The present disclosure generally relates to the field of electronics, and more particularly, to radio-frequency (RF) modules and devices.

### Description of Related Art

Orthogonal frequency division multiplexing (OFDM) is widely used in RF applications, such as wireless local area network (WLAN) applications (e.g., an 802.11 standard based network) and 5G applications.

### SUMMARY

In some implementations, the present disclosure relates to a method including receiving a first signal at a front-end module (FEM) including a power amplifier, the first signal indicating an increase in expected power or modulation; in response to receiving the first signal, increasing power at the power amplifier for one or more packets, and, after processing the one or more packets, reducing power at the power amplifier.

In some aspects, a method further includes receiving a second signal at the FEM, the second signal indicating a decrease in expected power or modulation. Power at the power amplifier may be reduced in response to receiving the second signal. In some aspects, the increased modulation is Modulation and Coding Scheme (MCS) 0.

The method may further include varying a load line of the power amplifier to increase power at the power amplifier. In some aspects, the FEM includes a controller and wherein the controller is configured to control an output lead of the power amplifier to vary the load line of the power amplifier. The power amplifier may include an inter-stage matching circuit configured to transform an impedance of the power amplifier to increase power at the power amplifier.

In some aspects, an output stage of the power amplifier includes multiple parallel sections. The method may include enabling one or more of the multiple parallel sections to increase power of the power amplifier. In some aspects, the method may include disabling one or more of the multiple parallel sections to decrease power of the power amplifier.

Each of the multiple parallel sections may include an inductor and/or two transistors. In some aspects, the method further includes, in response to receiving the first signal, simultaneously increasing increase a supply voltage and a load line applied to the power amplifier. The method may further include, in response to receiving the first signal, increasing saturation power at the power amplifier.

In some implementations, the present disclosure relates to a system including a front-end module (FEM) including a power amplifier and a controller configured to transmit a first signal to the FEM, the first signal indicating an increase in expected power or modulation, the FEM configured to increase power at the power amplifier in response to the first signal for one or more packets and decrease power at the power amplifier after processing the one or more packets.

The controller may be further configured to transmit a second signal to the FEM, the second signal indicating a decrease in expected power or modulation. In some aspects, the FEM is further configured to reduce power at the power amplifier in response to receiving the second signal.

In some implementations, the present disclosure relates to a method including receiving a first signal at a front-end module (FEM) including a power amplifier, the first signal indicating a first packet having an increased modulation, in response to receiving the first signal, increasing power at the power amplifier, processing the first packet, and, after processing the first packet, reducing power at the power amplifier.

Power may be increased at the power amplifier prior to the power amplifier receiving the first packet. In some aspects, a method further includes receiving a second signal at the FEM, the second signal indicating a second packet having a decreased modulation. Power at the power amplifier may be reduced in response to receiving the second signal.

### BRIEF DESCRIPTION OF THE DRAWINGS

Various embodiments are depicted in the accompanying drawings for illustrative purposes, and should in no way be interpreted as limiting the scope of the inventions. In addition, various features of different disclosed embodiments can be combined to form additional embodiments, which are part of this disclosure. Throughout the drawings, reference numbers may be reused to indicate correspondence between reference elements.

FIG. 1 depicts an example of a frequency division multiplexing (FDM) scheme where a frequency band includes a plurality of signals based on respective subcarrier tones.

FIG. 2 depicts an example of an orthogonal frequency division multiplexing (OFDM) scheme where a frequency band includes more densely packed subcarriers, such that neighboring pairs of signals based on respective subcarrier tones may overlap.

FIG. 3 depicts subcarrier tones for supporting the signals of the OFDM scheme of FIG. 2.

FIG. 4 shows an example of a subcarrier distribution associated with a 20 MHz OFDM signal for a WLAN application.

FIG. 5 shows an envelope of a typical OFDM signal, in time domain, that can result from the OFDM configuration of FIG. 4.

FIG. 6 provides a complementary cumulative distribution function (CCDF).

FIG. 7 provides a graph illustrating EVM versus output power for a typical Wi-Fi power amplifier.

FIG. 8 provides a graph illustrating EVM and power of a power amplifier at a constant Psat of 32 dBm.

FIG. 9 provides a graph illustrating EVM and power of a power amplifier at a constant Psat of 33 dBm.

FIG. 10 provides a graph illustrating EVM and power of a power amplifier with a variable Psat ranging from 27 dBm to 33 dBm.

FIG. 11 provides a graph illustrating EVM and power of a power amplifier with a variable Psat ranging from 32 dBm to 33 dBm.

FIG. 12 provides a schematic illustrating an RF portion of a Wi-Fi system.

FIG. 13 shows a process that can be performed by some or all of the OFDM systems described herein.

FIGS. 14A and 14B depict example wireless devices having one or more advantageous features described herein.

FIG. 15 is a schematic diagram of one embodiment of a load modulated power amplifier.

FIG. 16 is a schematic diagram of another embodiment of a load modulated power amplifier.

FIG. 17 is a schematic diagram of one embodiment of a load modulated power amplifier system.

FIG. 18 is a circuit diagram illustrating a multi-stage cascode power amplifier circuit according to one or more embodiments.

FIG. 19 provides a conceptual representation of the inter-stage matching circuitry.

FIG. 20 illustrates a power amplifier configured to disable sections of the output stage of the power amplifier through bias control.

FIG. 21 shows a semiconductor die having a substrate and including an OFDM system.

FIG. 22 shows a module having a packaging substrate and including an OFDM system.

FIG. 23 shows a wireless device including an OFDM system.

### DESCRIPTION

The headings provided herein, if any, are for convenience only and do not necessarily affect the scope or meaning of the claimed invention.

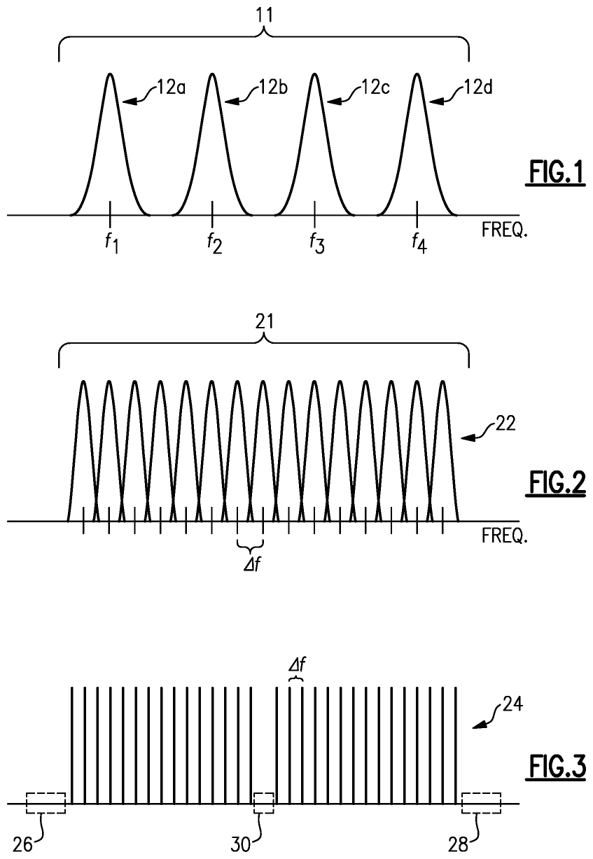

FIG. 1 depicts an example of a frequency division multiplexing (FDM) scheme where a frequency band 11 includes a plurality of signals (e.g., 12a, 12b, 12c, 12d) based on respective subcarrier tones (e.g., center frequencies f₁, f₂, f₃, f₄). In such a multiplexing scheme, the frequencies f₁, f₂, f₃, f₄ are separated sufficiently to avoid overlapping of neighboring signals. Accordingly, there is a limit on how closely subcarriers can be packed within a given frequency band width.

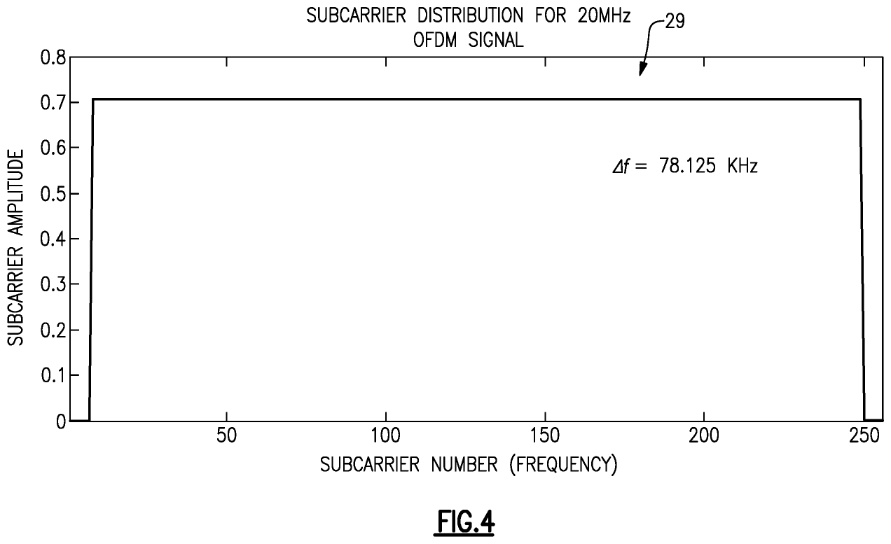

FIG. 2 depicts an example of an orthogonal frequency division multiplexing (OFDM) scheme where a frequency band 21 includes more densely packed subcarriers, such that neighboring pairs of signals 22 based on respective subcarrier tones may overlap. In the example of FIG. 2, each neighboring subcarrier tones is shown to have a frequency spacing of Δf. To accommodate the densely packed subcarriers, each subcarrier can be modulated with, for example, a digital modulation scheme, such that the subcarriers behave as orthogonal subcarriers.

FIG. 3 depicts subcarrier tones 24 for supporting the signals 22 of the OFDM scheme of FIG. 2. Similar to FIG. 2, each pair of neighboring subcarrier tones is shown to have a frequency spacing of Δf.

FIG. 3 further shows that an ODFM scheme can also include guard bands 26, 28 adjacent to the lower and upper frequency limits of the frequency band (20 in FIG. 2). Each of such guard bands can have a width to prevent interference with another frequency band; accordingly, each guard band can include a plurality of tone frequencies spaced by the same Δf. During ODFM operations, such frequencies of the guard bands are typically provided with null amplitudes.

FIG. 3 also shows that an ODFM scheme can also include a direct current (DC) subcarrier that separates two groups of subcarriers (e.g., first and second data subcarrier groups) within the frequency band (20 in FIG. 2). During ODFM operations, such a DC subcarrier is typically provided with a null amplitude.

The foregoing orthogonal frequency division multiplexing (OFDM) allows a high throughput of data transfer without necessarily relying on a high rate of data transmission. Thus, OFDM is widely used in radio-frequency (RF) applications such as wireless local area network (WLAN) applications (e.g., an 802.11 standard based network) and 5G applications.

It is noted that advantages provided by OFDM can include an ability to achieve very high throughputs, excellent compatibility with multiple-input and multiple-output (MIMO) architecture, and tolerance to multipath and fading that are common in RF environments.

A notable challenge associated with OFDM relates to a very high peak to average power ratio (PAPR) that can result when a large number of subcarriers with different frequencies are combined. For example, OFDM systems can exhibit PAPRs greater than 10 dB. Such a large PAPR can result in inefficient power amplification, since a power amplifier needs to be able to accurately amplify the peaks of the signal. Thus, in the context of the foregoing example where PAPR>10 dB, since the peaks are 10 dB higher than the average power, the power amplifier is typically large and inefficient. Typical power amplifier efficiencies at about 20% are common in OFDM applications, such that a power amplifier having such an efficiency value can consume 5 W to deliver 1 W of RF power to an antenna for transmission.

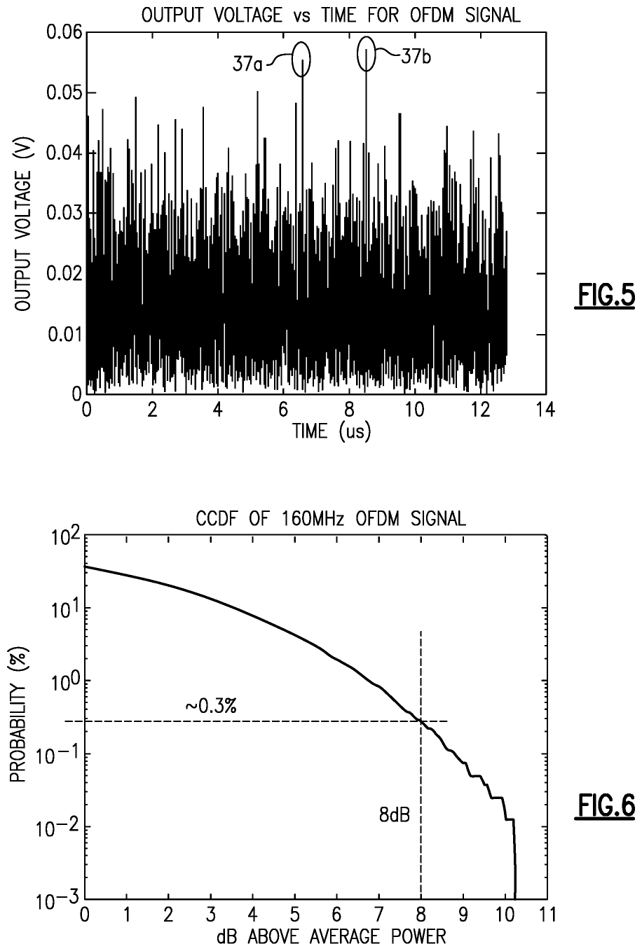

FIGS. 4 to 6 show various examples related to the foregoing power amplification inefficiency problem. FIG. 4 shows an example of a subcarrier distribution 29 associated with a 20 MHz OFDM signal for a WLAN application. Such an example OFDM signal includes a large number of subcarriers that are uniformly distributed in frequency, with a subcarrier spacing of approximately 78.125 kHz. Each subcarrier can be a sinewave with a respective magnitude and phase that are set by the data that is being transmitted. The magnitude and phase of each subcarrier are utilized to encode a respective portion of the transmitted data.

In the example of FIG. 4, there are guard bands at both edges of the channel supporting the subcarrier distribution 29, and such guard bands are configured to provide frequency separation between the channel and another channel. For example, the guard band on the lower frequency edge of the subcarrier distribution 29 can provide frequency separation between the channel and an adjacent channel on the left side of the channel. In another example, the guard band on the upper frequency edge of the subcarrier distribution 29 can provide frequency separation between the channel and an adjacent channel on the right side of the channel. In the example of FIG. 4, all of the subcarriers associated with the guard bands are all provided with zero amplitude.

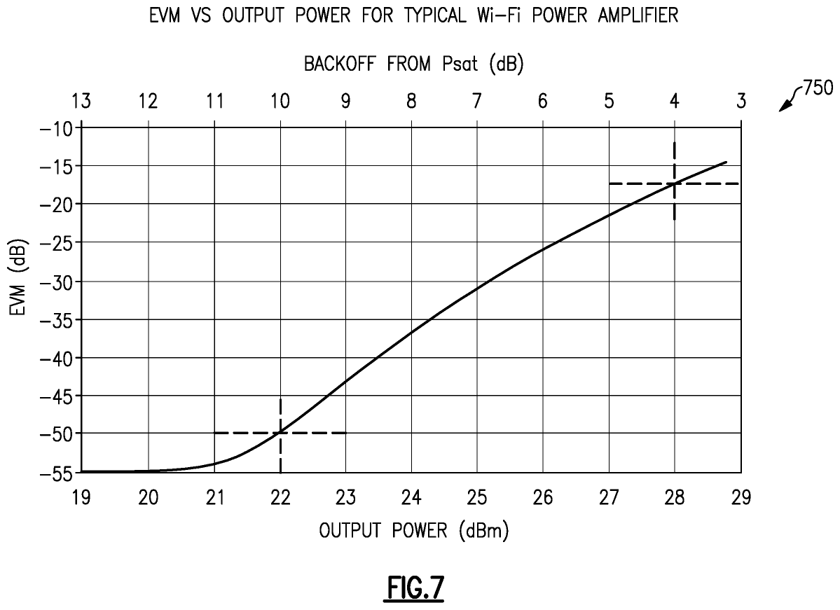

In the example OFDM configuration of FIG. 4, a high PAPR can result when random magnitude and phase of some or all of the subcarriers happen to add in phase to thereby result in constructive interference to produce large peaks in the signal. For example, FIG. 5 shows an envelope of a typical OFDM signal, in time domain, that can result from the OFDM configuration of FIG. 4.

In FIG. 5, large amplitude peaks such as peaks 37a, 37b can result in a high PAPR value for the OFDM signal. It is noted that such large amplitude peaks that produce the high PAPR value only occur for a very small portion of the signal duration time.

The foregoing property of a small portion of the signal that necessitates the high PAPR value can be characterized by a complementary cumulative distribution function (CCDF) as shown in FIG. 6. Such a CCDF provides the probability that any given signal level will exceed the average value. For example, for signal of FIG. 5, the signal is 8 dB higher than the average power approximately 0.3% of the time. In the example of FIGS. 5 and 6, the highest amplitude peak (32b) of the signal is shown to be approximately 10.2 dB in the CCDF of FIG. 6.

There may be an approximately 70% chance that the output power at any given time will be greater than approximately 4 dB below the average power. There is an approximately 38% chance that the output power will be more than the average power. There is an approximately 0.006% chance of finding a peak>10 dB above average.

It is noted that in some conventional OFDM applications, a clipping technique can be utilized, where any peaks in a signal generated from OFDM are simply clipped at baseband by passing the signal through a limiter. Such a technique typically results in degradation of error vector magnitude (EVM) performance and adjacent channel power ratio (ACPR) performance.

In another example, a conventional approach can include a pulse cancellation crest factor reduction (PC-CFR) technique. Such a technique typically analyzes a time domain data, identifies peak locations, and then adds an inverted pulse, aligned in time to each of the identified peaks of the signal to cancel the peaks. Such a cancelling pulse is typically shaped like a sin function, and application of such cancelling pulse(s) can reduce the PAPR by about 1 dB to 2 dB.

It is noted that the foregoing cancelling pulse is continuous in time, so application of such a pulse causes only a small amount of ACLR degradation. However, application of such a pulse causes a significant degradation in EVM. It is also noted that in OFDM systems involving higher order modulations like 1024 or 4096QAM, such a degradation in EVM is not acceptable or desirable.

In some RF applications where high linearity is desired, an OFDM signal having a high PAPR value is allowed to pass to an analog radio circuit and power amplifier without any clipping. Such a signal typically becomes distorted by the power amplifier, and the power amplifier operates in a very inefficient manner since it needs to be oversized to handle the high PAPR.

OFDM signals can be used in Wi-Fi systems. OFDM can offer many advantages, including excellent spectral efficiency (and hence high data throughput), good tolerance for fading required for mobile operation, and low complexity equalizers (suitable for high-performance, low-cost devices).

OFDM signals can have relatively high peak to average power ratios, and as a result, overall efficiency (defined as RF power out divided by DC power in) can be relatively low. Typical efficiencies can be approximately 10-20%.

Typically, radio systems for Wi-Fi use are designed to dissipate for a maximum allowed DC input power, and a maximum level of dissipated thermal power. For example, DC/DC converters can have a maximum current rating, and the heat sinks used in such systems can have a maximum rating to keep the components operating at acceptable temperatures.

Wi-Fi systems can operate over a range of output powers. In some cases, Wi-Fi systems operate at high powers with low levels of linearity to reach distant users. This mode of operation can result in the transmit chain dissipating maximum power, since a power amplifier is operating at high power. For example, a transmitter can transmit an OFDM signal using Binary Phase Shift Keying (BPSK) modulation at 27 dBm in order to reach a distant user. The power amplifier can dissipate, for example, 2 W to deliver 500 mW of RF power.

Wi-Fi systems can operate at lower output power when communicating with nearby users and/or to achieve maximum throughput. The power amplifier can operate at reduced power in order to have adequate linearity to transmit, for example, a 1024QAM or 4096QAM signal with the required linearity. For example, the power amplifier may back off its output power from 27 dBm (for BPSK) to 20 dBm in order to transmit a signal with adequate linearity to support 4096QAM. At this output power, the power dissipation can be significantly lower, with a typical power consumption of 1.2 W required to deliver 20 dBm. The lower output power of 20 dBm can significantly reduce the range of the 4096QAM signal.

Reconfiguring the transmit chain can allow systems to deliver more linear power in response to indications (e.g., signals) of an upcoming (e.g., future) transmission of a signal that requires a high level of linearity (e.g., 1024QAM or 4096QAM). The thermal budget of Wi-Fi devices can be sized to allow for approximately 2 W total power dissipation. Accordingly, there may be additional available DC power when operating at, for example, 1024QAM or 4096QAM. It may be advantageous to increase the 1024QAM/4096QAM capable power and/or reconfigure the power amplifier to dissipate up to 2 W of power in order to achieve these higher power levels.

The Modulation and Coding Scheme (MCS) defines the complexity of a modulation being used. MCS0 is bipolar phase shift keying, with two possible amplitude/phase states. MCS7 is a 64 Quadrature Amplitude Modulation (QAM) signal with 64 states, MCS9 is 256 QAM (256 states), MCS11 is 1024QAM (1024 states), and MCS13 is 4096QAM, with 4096 possible amplitude/phase states for each subcarrier. Various examples described herein describe systems and/or methods to increase 1024QAM or 4096QAM (e.g., MCS11, MCS13) compliant power without increasing power consumption when transmitting at lower order modulations BPSK and QPSK (e.g., MCS0, MCS2).

An ideal power amplifier may exhibit flat gain and flat phase versus output power until compression, at which time the gain will drop to 0 dB. If the output power attempts to increase beyond the maximum possible power that the power amplifier can deliver and/or the power at which the power amplifier is saturated (Psat), the power amplifier will hard clip the signal. When the average power of the signal is backed off more than approximately 11 dB from Psat, peaks may not exceed Psat and/or there may be no distortion.

As power is increased, the power amplifier may begin to clip the peaks more and more and this will cause the EVM to increase.

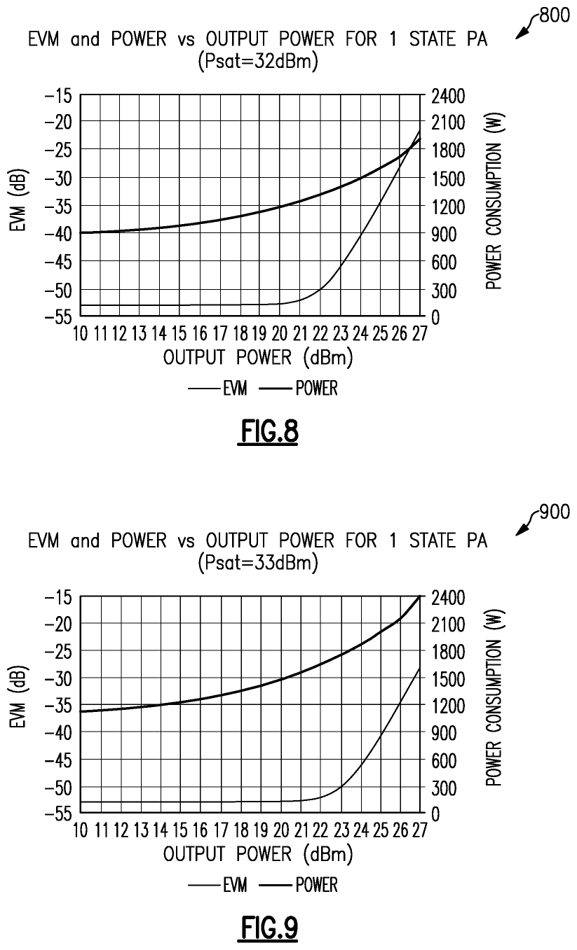

FIG. 7 provides a graph 750 illustrating EVM versus output power for a typical Wi-Fi power amplifier. The graph 750 also shows EVM as a function of backoff from the power amplifier's saturated output power (Psat).

To support 4096QAM, the EVM may need to be approximately-50 dB. Maximum output power may be approximately 22 dBm. Similarly, the power amplifier may need to be backed off approximately 10 dB from Psat to achieve this level of linearity.

With Psat at approximately 32 dBm, if the average power is 23 dBm (e.g., backoff is approximately 9 dB from Psat), clipping is minimal with only approximately 0.04% of the signal being clipped.

When power increases to approximately 25 dBm, clipping increases so that approximately 1% of the signal is clipped. Higher power can result in greater clipping and/or greater EVM degradation.

In order to meet linearity requirements for 1024QAM, the EVM needs to be less than-43 dB. This sets a lower bound on the power amplifier size, since the power amplifier must be sized so that Psat is 9 dB higher than the desired 1024-QAM rated power. For example, to deliver 1024QAM signal at 23 dBm, the minimum Psat may be approximately (23+9) or 32 dBm.

Psat may be the primary determinant of power consumption, since it sets the size of the power amplifier and its load line. Therefore, the overall power consumption of the power amplifier is largely determined by the required 1024-QAM compliant power, even though actual power consumption at the 1024QAM-rated power is much lower than power consumption at mask limited power.

To support MCS0, the EVM may only needs to be approximately-17 dB, and maximum output power may be approximately 28 dBm.

Equivalently, the power amplifier may need to be backed off approximately 4 dB from Psat to achieve this level of linearity. The power amplifier may be backed off by at least an additional 6 dB in order to achieve MCS13 capable linearity.

If a power amplifier has only a single transmit mode, the EVM vs. power and/or current vs. power curves may be fixed. To achieve MCS13 operation, the power amplifier may be backed off to operate at lower transmit powers. By increasing the power amplifier's saturated output power, the power amplifier's capable output power for all MCS levels can be increased. The compliant output power for each MCS may increase by approximately 1 dB for each dB increase in Psat.

However, by increasing Psat, power consumption may also increase. For MCS0 operation, increasing Psat may require significantly increasing power dissipation.

Some methods and/or systems described herein involve increasing the power amplifier's Psat levels only for high order modulations (MCS11, MCS13) and/or using a lower level of Psat for lower order modulations (MCS0 to MCS9).

At Psat-4 dB, the EVM may be approximately-15 dB. Power consumption at a Psat of 4 dB may be highest, whereas power consumption at a Psat of 9 dB (required for 1024QAM operation) may be much lower.

A typical power amplifier with a Psat of 32 dBm may consume approximately 2.05 W at 28 dBm and/or approximately 1.4 W at 23 dBm. By maintaining Psat at approximately 32 dBm for operation at 1024QAM and/or allowing Psat to be reduced at higher powers, power consumption may be reduced. Moreover, the power amplifier may have lower-15 dB EVM-compliant power.

For example, for a power amplifier with a Psat of approximately 32 dBm, approximately 23 dBm can be delivered with an EVM suitable for 1024QAM operation. If Psat is reduced to 30 dBm at 26 dBm, an EVM of 15 dB at 26 dBm (instead of 28 dBm, so at lower power) can be met. However, power consumption may be reduced at maximum power.

FIG. 8 provides a graph 800 illustrating EVM and power of a power amplifier at a constant Psat of 32 dBm. The power amplifier can achieve-50 dB EVM at approximately 22 dBm. −50 dB EVM may be limited by 10 dB backoff required from Psat. The power amplifier can have a maximum power at approximately 27 dBm and will consume approximately 1.9 W.

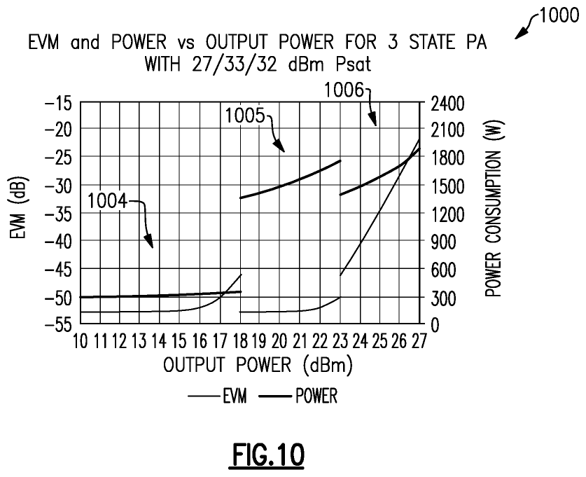

FIG. 9 provides a graph 900 illustrating EVM and power of a power amplifier at a constant Psat of 33 dBm. The power amplifier can achieve-50 dB EVM at approximately 23 dBm. The power amplifier can have a maximum power at approximately 27 dBm and will consume approximately 2.4 W. This amount of power consumption may be too high for the given DC and/or thermal power budgets. Note that with Psat=33 dBm, the power amplifier could deliver 28 dBm for MCS0 power, increasing the power combustion even further. The reference power is set at 27 dBm in this example to illustrate an increase in DC power consumption at constant output power when Psat is increased.

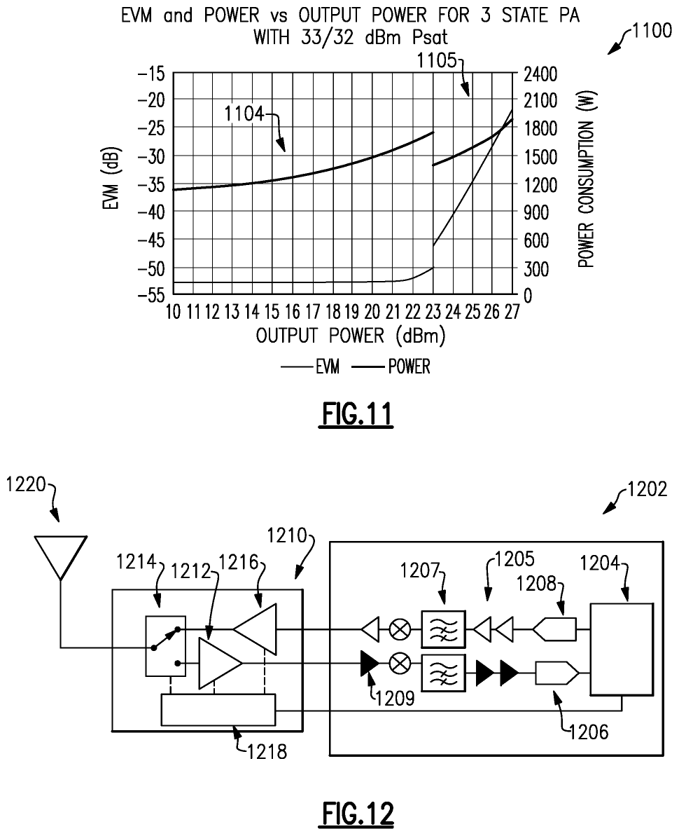

FIG. 10 provides a graph 1000 illustrating EVM and power of a power amplifier with a variable Psat ranging from 27 dBm to 33 dBm. At a low power state 1004, the Psat of the power amplifier may be set to approximately 27 dBm. At a medium power state 1005, the Psat of the power amplifier may be raised to approximately 33 dBm. At a high-power state 1006, the Psat of the power amplifier may be backed off to approximately 32 dBm.

When configured in state 1006 with Psat=32 dBm, the amplifier can achieve MCS0 power of 27 dBm, and will consume approximately 1.9 W. When configured to be in state 1005 with Psat-33 dBm, the power amplifier can achieve-50 dB EVM at approximately 23 dBm. −50 dB EVM may be limited by 10 dB backoff required from Psat. The power amplifier can have a maximum power at approximately 27 dBm and/or 1.8 W. However, the MCS13 power may be increased from 22 to 23 dBm. Note that the total power dissipated when operating in the MCS13 state will be no higher than the total power dissipated in the MCS0 state, so that the same thermal design can be used when operating in state 1005 that can be used as when operating in state 1006.

FIG. 11 provides a graph 1100 illustrating EVM and power of a power amplifier with a variable Psat ranging from 32 dBm to 33 dBm. At a low power state 1104, the Psat of the power amplifier may be set to approximately 33 dBm. At a high-power state 1105, the Psat of the power amplifier may be lowered to approximately 32 dBm.

Psat of the power amplifier can be changed in any of a variety of ways. In some examples, the power amplifier load impedance may be changed. For example, load line switching may be used and/or the power amplifier load impedance may be increased by switching to a different output matching network.

In another example, one or more transistors may be removed from the final drive stage of the power amplifier to effectively make the power amplifier smaller. Removing one or more transistors from the output array may be accomplished, for example, with switches and/or via de-biasing. In another example, Psat may be reduced by re-biasing the output stage of the power amplifier.

In another example, the DC voltage applied to the PA can be changed. Typically, higher supply voltages result in higher Psat.

These techniques can be applied individually, or they can be combined. For example, it may be advantageous to increase the DC supply voltage, and to simultaneously increase the load line applied to the power amplifier to achieve the best efficiency.

Various methods may be used to increase the MCS13-compliant output power by increasing the allowed power consumption.

In order to determine where to set Psat, a control signal may be received via a network device (e.g., Wi-Fi System Controller and/or System on a Chip (SoC)). A SoC is a component that contains digital, baseband, and low power RF functionality and/or can be used to drive an RF front-end module (FEM). The network device may be configured to communicate a target EVM and/or output power. The control signal may comprise and/or indicate a transmission mode to be used.

Such methods and systems may be utilized for any size power amplifier, include 3-state power amplifiers. In some examples, a 2-state and/or 4-state power amplifier can also be used. A control signal may be used to signal an exact desired level of linearity to be achieved.

Clipping can be performed at the power amplifier and/or in a baseband processor (e.g., prior to amplification). Clipping can have an identical effect on OFDM EVM regardless of where it is performed, assuming that the power amplifier is perfectly linear and/or does not contribute excess non-linearity.

The OFDM signal can be simultaneously clipped at the baseband processor and the power amplifier's Psat can be reduced to reduce power consumption. One advantage of clipping at the baseband processor may be taking advantage of filtering after clipping to improve mask.

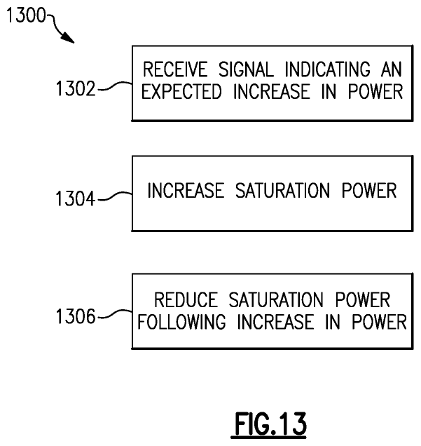

FIG. 12 provides a schematic illustrating an RF portion of a Wi-Fi system 1200. The system 1200 comprises a SoC 1202 comprising a baseband 1204, analog-to-digital converter (ADC 1206) and/or digital-to-analog converter (DAC 1208), and/or upconverter 1207. The system 1200 may comprise one or more amplifiers 1205 configured to drive an RF FEM 1210. The FEM 1210 may be configured to amplify one or more signals and/or connect to an antenna 1220.

The SoC 1202 may be configured to send control signals to the FEM 1210 to control a low noise amplifier (LNA 1212), switch 1214, and/or power amplifier 1216 of the FEM 1210. In some examples, the SoC 1202 may be configured to send a specific control signal to the power amplifier 1216 to indicate that the next and/or a future packet will be a high MCS packet (e.g., 4096QAM/MCS13). The power amplifier 1216 may be configured to reconfigure itself, in response to receiving the specific control signal, to increase its-50 dB EVM-compliant power. The power amplifier 1216 can be configured on a packet-by-packet basis, since the required MCS can vary on a packet-by-packet basis.

The FEM 1210 can further comprise a controller 1218 coupled to the power amplifier 1216, LNA 1212, and/or switch 1214. The controller 1218 may be configured to receive control signals from the SoC 1202. The SoC 1202 can further comprise an internal LNA (ILNA 1209).

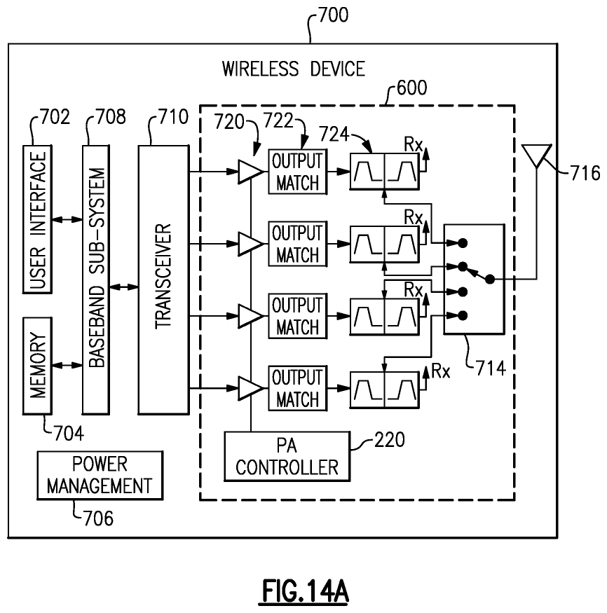

FIG. 13 shows a process 1300 that can be performed by some or all of the OFDM systems described herein. The process 1300 may be performed at or in association with a power amplifier to increase Psat in response to expected future delivery of one or more data packets using a high order modulation (e.g., 4096/MCS13).

In process block 1302, a signal may be received at a power amplifier and/or at a receiver in communication with the power amplifier. The signal may indicate an expected increase in power at the power amplifier and/or other associated devices and/or expected delivery of one or more packets using a high order modulation. The signal may comprise a target EVM and/or output power and/or may comprise a transmission mode to be used during the expected increase in power.

In some examples, the signal can indicate either an increase or decrease in expected power and/or expected MCS. In response, Psat can be adjusted accordingly.

At process block 1304, the saturation power of the power amplifier may be reduced in preparation for the expected increase in power. The saturation power may be reduced by any suitable means, which can include changing load impedance, removing (e.g., turning off) one or more transistors, and/or re-biasing an output stage of the power amplifier.

At process block 1306, the saturation power saturation may be increased following the expected increase in power.

It will be understood that one or more features of the present disclosure can be implemented for any OFDM system, including, for example, WLAN, 4G cellular, 5G cellular, and/or DOCSIS applications.

In some embodiments, one or more features of the present disclosure can be implemented utilizing, for example, algorithms and processors.

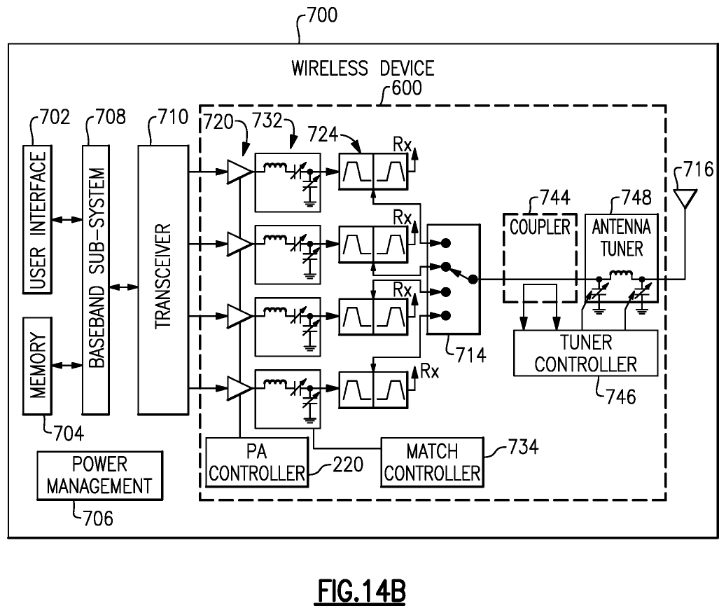

FIGS. 14A and 14B depict example wireless devices 700 having one or more advantageous features described herein. In the context of a module having one or more features as described herein, such a module can be generally depicted by a dashed box 600, and can be implemented as, for example, a front-end module (FEM). The devices 700 may comprise one or more power amplifiers (PAs) 720 with programmable load line(s). In some examples, (see, e.g., FIG. 14B) a PA 720 output load may be controlled to vary the PA 720 load line using adjustable components 732.

Psat=(Vdd−Vknee) 2/(2*RL), where Vdd is the supply voltage, Vknee is the knee voltage in the IV curve of the power transistor, and RL is the load resistance presented to the PA 720. Psat can be changed by either reducing RL or by increasing Vdd, or any combination of these. In some examples, Psat may be changed by altering RL.

Referring to FIG. 14A, PAs 720 can receive their respective RF signals from a transceiver 710 that can be configured and operated in known manners to generate RF signals to be amplified and transmitted, and to process received signals. The transceiver 710 is shown to interact with a baseband sub-system 708 that is configured to provide conversion between data and/or voice signals suitable for a user and RF signals suitable for the transceiver 710. The transceiver 710 can also be in communication with a power management component 706 that is configured to manage power for the operation of the wireless device 700. Such power management can also control operations of the baseband sub-system 708 and the module 600.

The baseband sub-system 708 is shown to be connected to a user interface 702 to facilitate various input and output of voice and/or data provided to and received from the user. The baseband sub-system 708 can also be connected to a memory 704 that is configured to store data and/or instructions to facilitate the operation of the wireless device, and/or to provide storage of information for the user.

In the example wireless device 700, outputs of the PAs 720 are shown to be matched (via respective output match circuits 722) and routed to their respective diplexers 724. Such amplified and filtered signals can be routed to an antenna 716 (or multiple antennas) through an antenna switch 714 for transmission. In some embodiments, the diplexers 724 can allow transmit and receive operations to be performed simultaneously using a common antenna (e.g., 716). In FIGS. 14A and 14B, received signals are shown to be routed to “Rx” paths (not shown) that can include, for example, a low-noise amplifier (LNA).

The wireless device 700 includes a power amplification controller (PA controller 220) configured to selectively control the PAs 720 to increase performance. The PA controller 220 can be configured, for example, to modify the load line based at least in part on the supply voltage, power output, and/or output impedance (e.g., the impedance of the output match circuits 722).

FIG. 14B illustrates an example implementation of a wireless device 700 that includes a power amplification controller 220, a match controller 734, and a tuner controller 746. In some embodiments, one or more of the power amplification controller 220, the match controller 734, and the tuner controller 746 can be implemented in a single controller (e.g., the PA controller 220). As described elsewhere herein, the PA controller 220, the match controller 734, and/or the tuner controller 746 can receive signals from the coupler 744, from a power or voltage supply, and/or other signals indicative of an output impedance and/or output power.

The PA controller 220 is configured to selectively enable and/or disable individual power amplifiers 720. The match controller 734 is configured to control the impedance of the output matching circuits 732. As illustrated, each output matching circuit 732 includes an inductive component and two variable capacitance components. The match controller 734, in some embodiments, controls the capacitance of individual output matching circuits 732 to provide a targeted output resistance. However, the output matching circuits 732 can be configured differently from the illustrated configuration. Similarly, individual output matching circuits 732 can differ from one another and need not be identical to one another.

The tuner controller 746 is configured to control an antenna tuner 748 that is coupled to the antenna 716. As illustrated, the antenna tuner 748 is configured with two variable capacitance components and an inductive component. The tuner controller 746, in certain embodiments, is configured to control the capacitances of the variable capacitance components to tune the output to the antenna 716. The tuner controller 746 can receive a signal from the coupler 744 that is correlated with the signal output from the antenna switch 714 module (ASM). The tuner controller 746 can be configured to configure the antenna tuner 748 based at least in part on the signal provided by the coupler 744.

FIG. 15 is a schematic diagram of one embodiment of a load modulated power amplifier 10. The load modulated power amplifier 10 includes a power amplifier 5 and a controllable load impedance 6. The load modulated power amplifier 10 amplifies an RF input signal RFIN to generate an RF output signal RFOUT.

The load modulated power amplifier 10 receives an envelope signal ENV that changes in relation to an envelope of the RF input signal RFIN. The envelope signal ENV is used to control an impedance of the controllable load impedance 6. For example, in this embodiment, the controllable load impedance 6 includes a series combination of an inductor 8 and a controllable capacitor 7, and the envelope signal ENV is used to control a capacitance of the controllable capacitor 7. Although one example of a controllable load impedance is depicted, the teachings herein are applicable to other implementations of controllable load impedances.

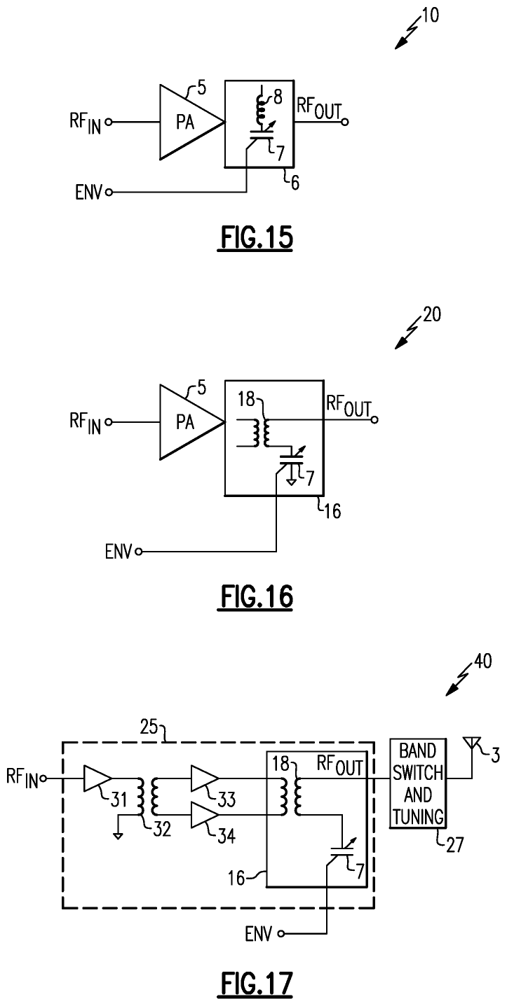

FIG. 16 is a schematic diagram of another embodiment of a load modulated power amplifier 20. The load modulated power amplifier 20 of FIG. 16 is similar to the load modulated power amplifier 10 of FIG. 15, except that the load modulated power amplifier 20 of FIG. 14 includes a different implementation of a controllable load impedance 16.

In particular, the controllable load impedance 16 includes a balun 18 and a controllable capacitor 7. An output of the power amplifier 5 drives a first winding of the balun 18. Additionally, a first terminal of a second winding of the balun 18 outputs the RF output signal RFOUT, while a second terminal of the second winding is coupled to the controllable capacitor 7. The controllable capacitor 7 is controlled by the envelope signal ENV.

Changing a value of the controllable capacitor 7 effectively resonates out some of the inductance of the second winding, thereby effectively changing a turn ratio of the balun 18.

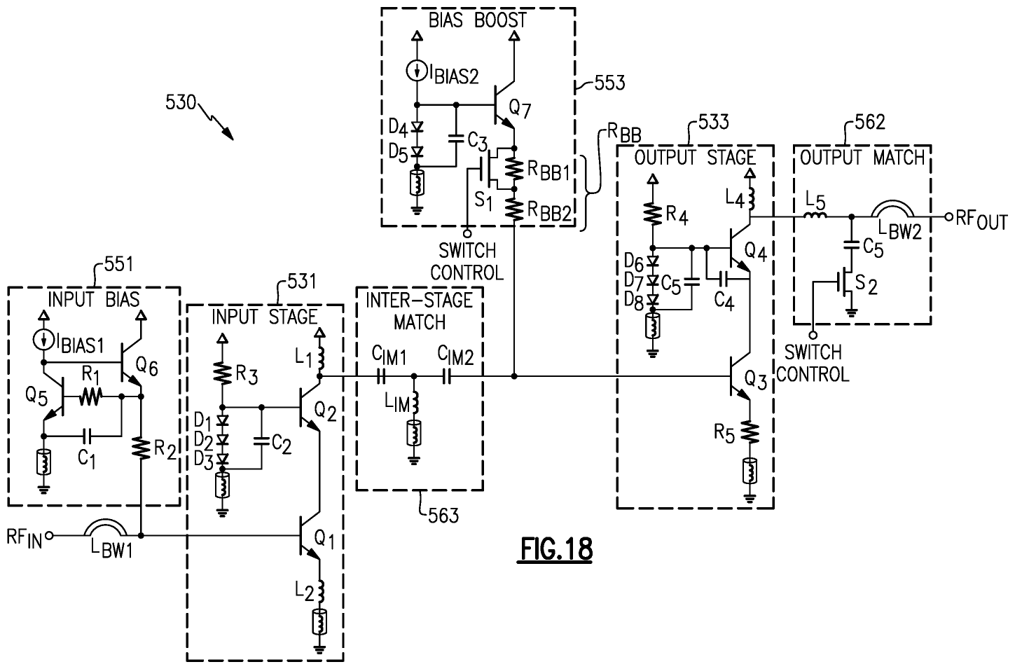

FIG. 17 is a schematic diagram of one embodiment of a load modulated power amplifier system 40. The load modulated power amplifier system 40 includes a load modulated power amplifier 25, a band switching and tuning circuit 27, and an antenna 3. In the illustrated embodiment, the load modulated power amplifier 25 includes a driver amplifier 31, an input balun 32, a first output amplifier 33, a second output amplifier 34, and a controllable load impedance 16 that includes an output balun 18 and a controllable capacitor 7.

The load modulated power amplifier 25 is implemented as a push-pull amplifier, in this embodiment. Additionally, an output of the first output amplifier 33 is connected to a first terminal of a first winding of the balun 18, while an output of the second output amplifier 34 is connected to a second terminal of the first winding of the balun 18.

FIG. 18 is a circuit diagram illustrating a multi-stage cascode power amplifier circuit 530 according to one or more embodiments. In one embodiment, the amplifier circuit 530 may represent a 5-6 GHz cascode power amplifier design, which may be implemented in a BiCMOS process, for example. In certain embodiments, all or a portion of the illustrated components may be formed and/or mounted in a single chip or die. In an embodiment, an RF input signal is transmitted to the circuit 530 over a metal connector that is connected between the chip associated with the circuit 530 and a printed circuit board (PCB). Such connector may provide an inductance LBW1, which may be used as part of a matching component for the input of the amplifier circuit 530. In certain alternative embodiments, matching inductance is provided by one or more discrete inductors and/or other passive devices or elements. The inductance of the wire connector LBW1 may be approximately 500 pF, or some other value. The input matching may further be accomplished (e.g., for 5-6 GHZ) using an emitter inductor L2 in combination with the input bond wire LBW1 to form a two-element broad-band matching network to match the circuit to an input impedance (e.g., 50 ohms) across a target bandwidth (e.g., 1 GHz bandwidth).

The circuit 530 includes input bias circuitry 551, which receives input power from the RF input signal and outputs a current level into the base of the driver transistor Q1. In order to prevent the bias circuitry 551 from increasing the current to the amplifier by too great an amount, the circuitry 551 includes a resistor R2 configured to control the amount of input power that is seen by the bias circuit 551. In certain embodiments, R2 provides an RF choke to at least partially isolate the bias circuit 551 from the RF signal. Because the resistor R2 may at least partially control the amount of gain expansion in the circuit, it may be desirable for the value of R2 to be chosen such that the gain of the amplifier remains substantially flat over an operational range of the amplifier. With a relatively large resistor value, a relatively constant current may flow into the amplifier; as the signal power increases, the transistor Q1 may at least partially compress, causing the gain to drop. With a relatively small resistor value, as the power level increases, causing the transistor Q1 to compress and become nonlinear, a higher current level may be injected into the base of the transistor Q1 to effectively offset the nonlinearity caused by increased power.

The input stage 531 of the circuit 530 may include DC bias circuitry coupled to the base of the cascode transistor Q2. As a nonlinear device, the base-to-emitter voltage of the transistor Q2 may be sensitive to the signal power level present at the base due to, for example, second-order distortion. Therefore, in certain embodiments, the base of each cascode transistor of the circuit (e.g., Q2, Q4) may be AC-grounded through a relatively large capacitor, which may advantageously be connected as closely as possible to the base of the transistor. However, in certain embodiments, even relatively large capacitor values (e.g., 15 pF for C2 and/or 25 pF for C5) may not provide sufficient grounding at the base of the transistor(s). When the voltage swings become large, such node(s) may experience changes in the bias level. In order to reduce this effect, diodes may be utilized to provide a relatively constant bias voltage to the bases of the cascode transistors. In the illustrated circuit 530, three diodes are used (D1, D2 and D3 for transistor Q2; and D6, D7 and D8 for transistor Q4) to provide a bias voltage of, for example, about 2.4 V to the base of the cascode transistor(s). Such a configuration may result in a VCE of approximately 1.5 V for both transistor Q1 and transistor Q3, which may keep them out of saturation and also provide sufficient head room for the transistor Q2 and the transistor Q4.

The input stage 531 of the power amplifier 530 may be designed as a class-A amplifier with a peak voltage swing not to exceed 3 V, for example. An RF choke inductor L1 may provide bias to the input stage 531. The load line and current for the input stage 531 may be designed to allow for the amplifier to remain linear and allow the design performance to be substantially limited by the output stage 533.

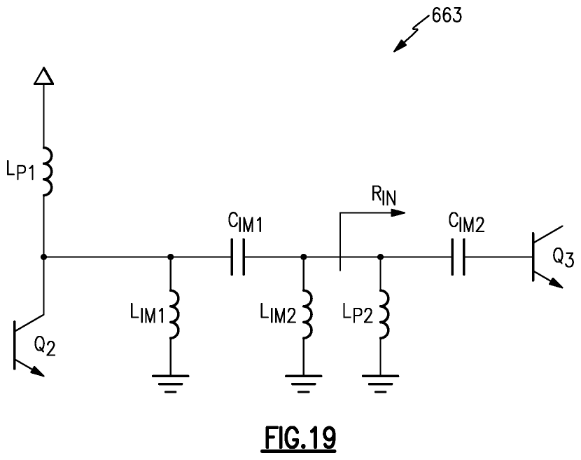

The circuit 530 includes inter-stage matching circuitry 563 configured to connect the two active amplifier stages. FIG. 19 provides a conceptual representation of the inter-stage matching circuitry 563. As shown in FIG. 19, LP2 and CIM2 may form a conventional LC matching network to transform the input impedance of Q3 into a real impedance. In certain embodiments, a relatively low impedance may be used to broaden the bandwidth of the match. In addition, LIM and CIM1 (see FIG. 5) may form a lumped-element left-handed transmission line. The various elements of the inter-stage matching circuitry 563 may be sized so that the electrical length of the transmission line is approximately a quarter wavelength with respect to the fundamental frequency of the transmission signal. Thus, the input impedance of the output stage 533 may advantageously be transformed into a desired load line that is optimal for the input stage 531.

The circuit 530 may include bias boost circuitry 553 connected in parallel to the transmission path at the base of the driver transistor Q3 of the output stage. The use of a bias boosting cell may help to flatten the power added efficiency (PAE) curve of the circuit 530.

The third-order term of the output current power series may become negative even with a small amount of degeneration REB. Thus, the gain may compress at relatively high input amplitudes. Such compression may set in prior to compression at the output due to relatively large voltage swings, which may cause the transistor to enter the saturation region.

At low input levels, the gain may be relatively flat; however, as the input level rises, if the collector current remains substantially constant, the gain may fall off causing the amplifier to compress. In order to compensate for such effects, the bias boosting cell 553 may be designed to make IC4 proportional to vs as well. With proper design/control, the gain curve may thereby be at least partially flattened. In order to achieve such gain linearity, the combination of the resistor(s) RBB and the transistor Q7 may be implemented as a power detector.

In one embodiment, the second stage, or output stage, 533 of the power amplifier 530 may be designed to have a 1 dB compression point of at least, for example, 26 dBm. Such a design may allow for linear operation for an average transmit power of, for example, 19 dBm. Within the output stage 533, the transistor device Q3 may be a relatively high performance BJT, while the transistor device Q4 may be a relatively high power BJT designed to handle relatively large output swings and collector voltages. Both devices may be sized such that, at a power level of approximately 26 dBm, the average current flow may provide a bias close to peak fT. In an embodiment, such a design may result in an emitter area of approximately 1600 μm2 for one or more of the transistors Q3, Q4. It should be noted that a cascode design, which may have a relatively lower output swing compared to a common-emitter power amplifier, may provide a relatively smaller optimum load resistance, which may lead to relatively higher average current and/or larger device area; a cascode design may therefore require more than twice the transistor area of a typical common-emitter design for the same power level.

It may be desirable for the load line may be chosen conservatively to avoid the cascode transistor Q4 entering a saturation state, which may cause undesirable power-dependent phase shift through the device. In addition, a capacitor C4 may be added to place a linear capacitance in parallel with CTT4 to further linearize the phase shift through the device to a higher power level. For example, the cascode transistor Q4 may cause AM-PM distortion to a greater extent than the driver transistor Q3 in certain embodiments in view of such voltage swings; the driver transistor Q3 may see a relatively smaller voltage swing, and may therefore be more linear. Therefore, the circuit 530 includes an AM-PM distortion compensating capacitor C4 between the emitter of the cascode transistor Q4 and its base.

DC bias circuitry including one or more resistors (e.g., R4), diodes (e.g., diodes D6, D7, D8), and/or capacitors (e.g., C5) may be connected in parallel at the base of the cascode transistor Q4. The bias circuitry may provide a DC voltage to the base of the cascode transistor Q4. The capacitor C5 may serve to provide a ground reference at the base of the transistor Q4 with respect to RF signals, resulting in a substantially fixed DC value at the base of the transistor Q4.

According to certain embodiments, the values of C4, R2 and/or RBB may be selected to provide optimal AM-PM performance. Selection of values for such devices may be based on simulation. For example, because the transistors of the circuit may handle relatively large signals, they may generally operate in a relatively nonlinear manner, and therefore simulation may be a desirable means for identifying the desired resistor and/or capacitor values.

The output matching network 562 may incorporate an LCL network to transform, for example, a 50-ohm load to the optimal load impedance (e.g., for 26 dBm at 5 V). In order to increase the efficiency when the power amplifier is operating at a lower output power, the load line may be switched using a switch S2, such as an NFET device. The switched resistance may provide approximately four times the load resistance in certain embodiments, and thus increase efficiency of the design while possibly reducing the output power to, for example, 20 dBm or lower.

The illustrated switchable load line technique based on control of the switch S2 may provide increased power-added efficiency when the power amplifier is delivering lower output power. In one example implementation, the circuit design of FIG. 5 may implement a 5 V power supply to achieve a peak PAE of approximately 29%, and a 1 dB compression point of approximately 26.5 dBm. Therefore, the power amplifier circuit 530 may be matched to the load with the use of a switchable output matching network. The switchable output matching network may comprise one or more inductors, or inductive elements. For example, an inductance LBW2 may be provided by an inductor formed with a bond wire in certain embodiments.

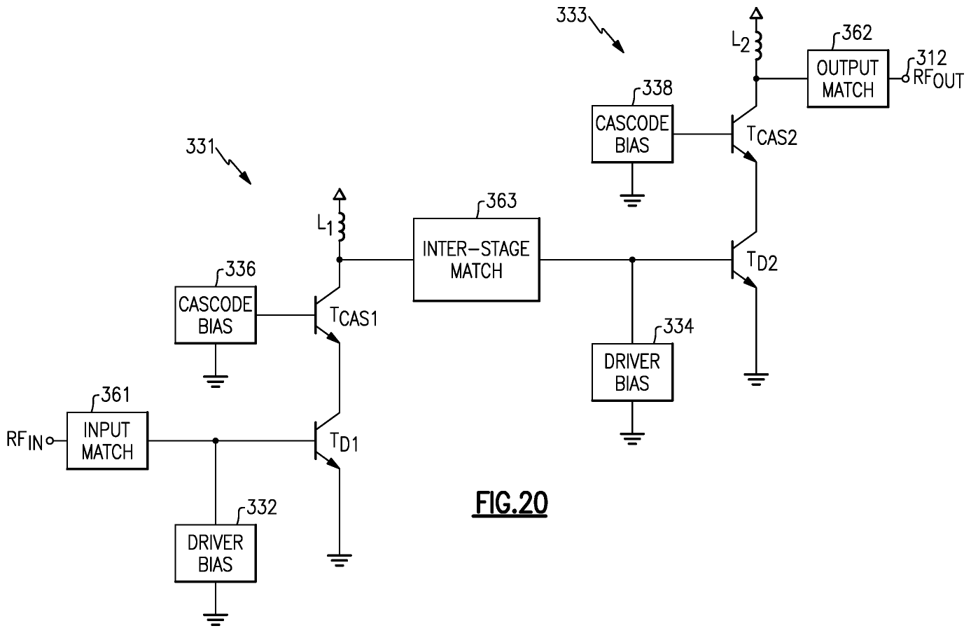

FIG. 20 illustrates a power amplifier configured to disable sections of the output stage 333 of the power amplifier through bias control. The output stage 333 can comprise an inductor L2, a first transistor Tcas2, and/or a second transistor TD2. The output stage 333 can comprise multiple parallel sections. These sections can be enabled or disabled by suitable application of the cascode bias. If all sections are enabled by turning bias on, the power amplifier output power and/or Psat can be maximized. If one or more sections are disabled by turning the bias to that section off, then the power amplifier output power and/or Psat can be reduced.

In certain embodiments, one or more of the amplifier stages 331, 333 may include cascode biasing circuitry (336, 338), such as a DC voltage source, or the like, connected between the base of the cascode transistor and ground to provide DC voltage to the base of the cascode transistor. In certain embodiments, a capacitor (not shown), or some type of capacitance, may be connected between the base and emitter (or collector) of the cascode transistor of one or more of the amplifier stages. For example, in cascode transistor topologies, the cascode transistor (e.g., TCAS1, TCAS2) may be subject to AM-PM distortion due to voltage swing volatility. Therefore, in certain embodiments, a linearizing capacitor (not shown) may be placed in parallel with the base-emitter capacitance of the cascode transistor of one or more stages of the power amplifier circuit 361. Such capacitor placement may allow for modification of the shape of the AM-PM curve by selecting an optimized size for the capacitor. The circuit may comprise an inter-stage match 363 between the input stage 331 and the output stage 333.

FIGS. 21 to 23 show examples of various products where one or more features of the present disclosure can be implemented. For example, FIG. 21 shows that in some embodiments, a semiconductor die 300 having a substrate 302 can include an OFDM system 100 having one or more features as described herein.

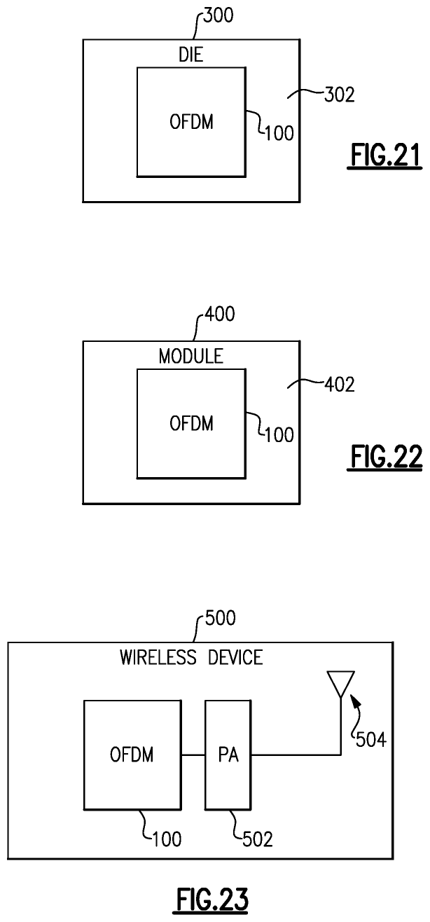

In another example, FIG. 22 shows that in some embodiments, a module 400 having a packaging substrate 402 can include an OFDM system 100 having one or more features as described herein. Such an OFDM system may or may not be implemented on a common die.

In yet another example, FIG. 23 shows that in some embodiments, a wireless device 500 can include an OFDM system 100 having one or more features as described herein. In some embodiments, such an OFDM system can be implemented to provide a multiplexed signal with a reduced PAPR to a power amplifier 502. An amplified signal from the power amplifier 502 can be transmitted through an antenna 504.

The present disclosure describes various features, no single one of which is solely responsible for the benefits described herein. It will be understood that various features described herein may be combined, modified, or omitted, as would be apparent to one of ordinary skill. Other combinations and sub-combinations than those specifically described herein will be apparent to one of ordinary skill, and are intended to form a part of this disclosure. Various methods are described herein in connection with various flowchart steps and/or phases. It will be understood that in many cases, certain steps and/or phases may be combined together such that multiple steps and/or phases shown in the flowcharts can be performed as a single step and/or phase. Also, certain steps and/or phases can be broken into additional sub-components to be performed separately. In some instances, the order of the steps and/or phases can be rearranged and certain steps and/or phases may be omitted entirely. Also, the methods described herein are to be understood to be open-ended, such that additional steps and/or phases to those shown and described herein can also be performed.

Some aspects of the systems and methods described herein can advantageously be implemented using, for example, computer software, hardware, firmware, or any combination of computer software, hardware, and firmware. Computer software can comprise computer executable code stored in a computer readable medium (e.g., non-transitory computer readable medium) that, when executed, performs the functions described herein. In some embodiments, computer-executable code is executed by one or more general purpose computer processors. A skilled artisan will appreciate, in light of this disclosure, that any feature or function that can be implemented using software to be executed on a general-purpose computer can also be implemented using a different combination of hardware, software, or firmware. For example, such a module can be implemented completely in hardware using a combination of integrated circuits. Alternatively or additionally, such a feature or function can be implemented completely or partially using specialized computers designed to perform the particular functions described herein rather than by general purpose computers.

Multiple distributed computing devices can be substituted for any one computing device described herein. In such distributed embodiments, the functions of the one computing device are distributed (e.g., over a network) such that some functions are performed on each of the distributed computing devices.

Some embodiments may be described with reference to equations, algorithms, and/or flowchart illustrations. These methods may be implemented using computer program instructions executable on one or more computers. These methods may also be implemented as computer program products either separately, or as a component of an apparatus or system. In this regard, each equation, algorithm, block, or step of a flowchart, and combinations thereof, may be implemented by hardware, firmware, and/or software including one or more computer program instructions embodied in computer-readable program code logic. As will be appreciated, any such computer program instructions may be loaded onto one or more computers, including without limitation a general-purpose computer or special purpose computer, or other programmable processing apparatus to produce a machine, such that the computer program instructions which execute on the computer(s) or other programmable processing device(s) implement the functions specified in the equations, algorithms, and/or flowcharts. It will also be understood that each equation, algorithm, and/or block in flowchart illustrations, and combinations thereof, may be implemented by special purpose hardware-based computer systems which perform the specified functions or steps, or combinations of special purpose hardware and computer-readable program code logic means.

Furthermore, computer program instructions, such as embodied in computer-readable program code logic, may also be stored in a computer readable memory (e.g., a non-transitory computer readable medium) that can direct one or more computers or other programmable processing devices to function in a particular manner, such that the instructions stored in the computer-readable memory implement the function(s) specified in the block(s) of the flowchart(s). The computer program instructions may also be loaded onto one or more computers or other programmable computing devices to cause a series of operational steps to be performed on the one or more computers or other programmable computing devices to produce a computer-implemented process such that the instructions which execute on the computer or other programmable processing apparatus provide steps for implementing the functions specified in the equation(s), algorithm(s), and/or block(s) of the flowchart(s).

Some or all of the methods and tasks described herein may be performed and fully automated by a computer system. The computer system may, in some cases, include multiple distinct computers or computing devices (e.g., physical servers, workstations, storage arrays, etc.) that communicate and interoperate over a network to perform the described functions. Each such computing device typically includes a processor (or multiple processors) that executes program instructions or modules stored in a memory or other non-transitory computer-readable storage medium or device. The various functions disclosed herein may be embodied in such program instructions, although some or all of the disclosed functions may alternatively be implemented in application-specific circuitry (e.g., ASICs or FPGAs) of the computer system. Where the computer system includes multiple computing devices, these devices may, but need not, be co-located. The results of the disclosed methods and tasks may be persistently stored by transforming physical storage devices, such as solid-state memory chips and/or magnetic disks, into a different state.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number, respectively. The word “or” in reference to a list of two or more items, that word covers all of the following interpretations of the word: any of the items in the list, all of the items in the list, and any combination of the items in the list. The word “exemplary” is used exclusively herein to mean “serving as an example, instance, or illustration.” Any implementation described herein as “exemplary” is not necessarily to be construed as preferred or advantageous over other implementations.

The disclosure is not intended to be limited to the implementations shown herein. Various modifications to the implementations described in this disclosure may be readily apparent to those skilled in the art, and the generic principles defined herein may be applied to other implementations without departing from the spirit or scope of this disclosure. The teachings of the invention provided herein can be applied to other methods and systems, and are not limited to the methods and systems described above, and elements and acts of the various embodiments described above can be combined to provide further embodiments. Accordingly, the novel methods and systems described herein may be embodied in a variety of other forms; furthermore, various omissions, substitutions, and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A method comprising:
receiving a first signal at a front-end module (FEM) comprising a power amplifier, the first signal indicating an increase in expected power or modulation;
in response to receiving the first signal, increasing power at the power amplifier for one or more packets; and
after processing the one or more packets, reducing power at the power amplifier.

2. The method of claim 1 further comprising receiving a second signal at the FEM, the second signal indicating a decrease in expected power or modulation.

3. The method of claim 2 wherein power at the power amplifier is reduced in response to receiving the second signal.

4. The method of claim 1 wherein the increased modulation is Modulation and Coding Scheme (MCS) 0.

5. The method of claim 1 further comprising varying a load line of the power amplifier to increase power at the power amplifier.

6. The method of claim 5 wherein the FEM comprises a controller and wherein the controller is configured to control an output lead of the power amplifier to vary the load line of the power amplifier.

7. The method of claim 1 wherein the power amplifier comprises an inter-stage matching circuit configured to transform an impedance of the power amplifier to increase power at the power amplifier.

8. The method of claim 1 wherein an output stage of the power amplifier comprises multiple parallel sections.

9. The method of claim 8 further comprising enabling one or more of the multiple parallel sections to increase power of the power amplifier.

10. The method of claim 8 further comprising disabling one or more of the multiple parallel sections to decrease power of the power amplifier.

11. The method of claim 8 wherein each of the multiple parallel sections comprises an inductor and two transistors.

12. The method of claim 1 further comprising, in response to receiving the first signal, simultaneously increasing increase a supply voltage and a load line applied to the power amplifier.

13. The method of claim 1 further comprising, in response to receiving the first signal, increasing saturation power at the power amplifier.

14. A system comprising:
a front-end module (FEM) comprising a power amplifier; and
a controller configured to transmit a first signal to the FEM, the first signal indicating an increase in expected power or modulation;
the FEM configured to increase power at the power amplifier in response to the first signal for one or more packets and decrease power at the power amplifier after processing the one or more packets.

15. The system of claim 14 wherein the controller is further configured to transmit a second signal to the FEM, the second signal indicating a decrease in expected power or modulation.

16. The system of claim 15 wherein the FEM is further configured to reduce power at the power amplifier in response to receiving the second signal.

17. A method comprising:
receiving a first signal at a front-end module (FEM) comprising a power amplifier, the first signal indicating a first packet having an increased modulation;
in response to receiving the first signal, increasing power at the power amplifier;
processing the first packet; and
after processing the first packet, reducing power at the power amplifier.

18. The method of claim 17 wherein power is increased at the power amplifier prior to the power amplifier receiving the first packet.

19. The method of claim 17 further comprising receiving a second signal at the FEM, the second signal indicating a second packet having a decreased modulation.

20. The method of claim 19 wherein power at the power amplifier is reduced in response to receiving the second signal.
